(19) United States
(12) Patent Application Publication
(10) Pub. No.: US 2021/0208214 A1
(43) Pub. Date: Jul. 8, 2021

(54) MAGNETIC SENSOR CALIBRATION METHOD AND MOBILE PLATFORM

(71) Applicant: SZ DJI TECHNOLOGY CO., LTD., Shenzhen (CN)

(72) Inventors: Huasen ZHANG, Shenzhen (CN); Chaobin CHEN, Shenzhen (CN)

(21) Appl. No.: 17/211,218

(22) Filed: Mar. 24, 2021

Related U.S. Application Data
(63) Continuation of application No. PCT/CN2018/108464, filed on Sep. 28, 2018.

(51) Int. Cl. G01R 33/00

(52) U.S. Cl. CPC G01R 33/0035

(57) ABSTRACT

A magnetic sensor calibration method includes obtaining a relative movement parameter between a mobile magnetic member of a mobile platform and a magnetic sensor of the mobile platform during movement of the mobile magnetic member and calibrating sensor data output by the magnetic sensor according to the relative movement parameter. The mobile magnetic member and the magnetic sensor are not rigidly connected.

### CROSS-REFERENCE TO RELATED APPLICATION

This application is a continuation of International Application No. PCT/CN2018/108464, filed Sep. 28, 2018, the entire content of which is incorporated herein by reference.

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### TECHNICAL FIELD

The present disclosure generally relates to the electronic technology field and, more particularly, to a magnetic sensor calibration method and a mobile platform.

### BACKGROUND

A magnetic sensor (e.g., a compass) is a sensor that functions by measuring a magnetic field. A parameter (e.g., head direction) can be measured by measuring the magnetic field. The magnetic sensor can be carried by a mobile platform. Certain parameters of the mobile platform are detected by the magnetic sensor.

Certain members (e.g., magnetic members) of the mobile platform will generate a magnetic field interference. The magnetic field interference will impact parameter measurement of the magnetic sensor such that the parameters detected by the magnetic sensor are inaccurate. Currently, a ∞-shaped calibration method in space is used to calibrate the magnetic sensor. The method can compensate for the magnetic field interference caused by the components rigidly connected to the magnetic sensor. Moreover, in the structure of the mobile platform, some components that are not rigidly connected to the magnetic sensor moves relative to the magnetic sensor and have a strong magnetic field interference on the magnetic sensor. The interference caused by the components that are not rigidly connected to the magnetic sensor cannot be effectively calibrated, which will affect the accuracy of the parameter measurement by the magnetic sensor.

### SUMMARY

Embodiments of the present disclosure provide a magnetic sensor calibration method. The method includes obtaining a relative movement parameter between a mobile magnetic member of a mobile platform and a magnetic sensor of the mobile platform during movement of the mobile magnetic member and calibrating sensor data output by the magnetic sensor according to the relative movement parameter. The mobile magnetic member and the magnetic sensor are not rigidly connected.

Embodiments of the present disclosure provide a mobile platform including a mobile magnetic member, a magnetic sensor, and a processor. The magnetic sensor is not rigidly connected to the mobile magnetic member. The processor is configured to obtain a relative movement parameter between the mobile magnetic member and the magnetic sensor during movement of the mobile magnetic member and calibrate sensor data output by the magnetic sensor according to the relative movement parameter.

### BRIEF DESCRIPTION OF THE DRAWINGS

FIG. 1 is a schematic architecture diagram of an unmanned aerial system according to some embodiments of the present disclosure.

FIG. 2 is a schematic flowchart of a magnetic sensor calibration method according to some embodiments of the present disclosure.

FIG. 3 is a schematic flowchart showing obtaining a correspondence between a relative movement parameter and a calibration parameter according to some embodiments of the present disclosure.

FIG. 4 is a schematic flowchart showing obtaining the calibration parameter of the magnetic sensor according to some embodiments of the present disclosure.

FIG. 5 is a schematic structural diagram of a mobile platform according to some embodiments of the present disclosure.

### DETAILED DESCRIPTION OF THE EMBODIMENTS

To make purposes, technical solutions, and advantages of the present disclosure clearer, the technical solutions in embodiments of the present disclosure are described in conjunction with accompanying drawings in embodiments of the present disclosure. The described embodiments are only some embodiments not all the embodiments of the present disclosure. Based on the embodiments of the disclosure, all other embodiments obtained by those of ordinary skill in the art without any creative work are within the scope of the present disclosure.

When an assembly is “fixed to” another assembly, the assembly may be directly on the other component, or an intermediate assembly may also exist. When an assembly is considered to be “connected” to another assembly, the assembly can be directly connected to another assembly or connected to the another assembly through an intermediate assembly.

Unless otherwise specified, all technical and scientific terms used herein have the same meaning as commonly understood by those skilled in the technical field of the present disclosure. The terms used in the specification of the present disclosure herein are only for the purpose of describing specific embodiments and are not intended to limit the present disclosure. The term “and/or” as used herein includes any and all combinations of one or more related listed items.

In connection with the accompanying drawings, embodiments of the present disclosure are described in detail below. When there is no conflict, embodiments and features of embodiments may be combined with each other.

Embodiments of the present disclosure provide a magnetic sensor calibration method and a mobile platform. A magnetic sensor may be a sensor that functions by sensing the magnetic field, for example, a compass, a magnetometer, a position sensor, etc. The mobile platform, for example, may include an unmanned aerial vehicle (UAV), an unmanned ship, an unmanned vehicle, a robot, etc. The UAV may include a rotorcraft, for example, a multi-rotor aircraft propelled by a plurality of propellers through the air, which is not limited by embodiments of the present disclosure.

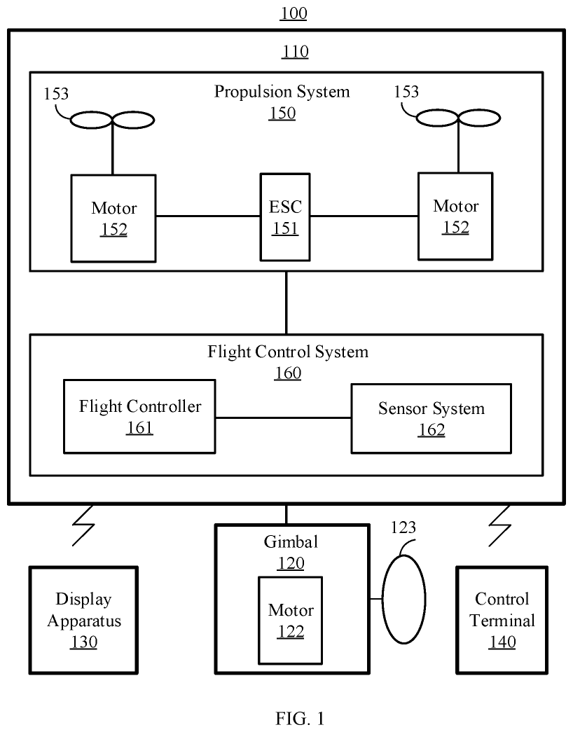

FIG. 1 is a schematic architecture diagram of an unmanned aerial system 100 according to some embodiments of the present disclosure. In some embodiments, the rotorcraft is described as an example.

The unmanned aerial system 100 includes a UAV 100, a display apparatus 130, and a control terminal 140. The UAV includes a propulsion system 150, a flight control system 160, a vehicle frame, and a gimbal 120 carried by the vehicle frame. The UAV 110 may communicate with the control terminal 140 and the display apparatus 130 wirelessly.

The vehicle frame includes a vehicle body and a stand (also referred to as a landing stand). The vehicle body includes a central frame and one or more arms connected to the central frame. The one or more arms extend radially from the central frame. The stand is connected to the vehicle body and is configured to support the UAV during landing.

The propulsion system 150 includes one or more electronic speed controllers (ESC) 151, one or more rotors 153, and one or more motors 152 corresponding to the one or more rotors 153. A motor 152 is connected between an ESC 151 and a rotor 153. The motor 152 and the rotor 153 are arranged at the arm of the UAV 110. The ESC 151 may be configured to receive a drive signal generated by the flight control system 160 and may provide drive current to the motor 152 according to the drive signal to control the rotation speed of the motor 152. The motor 152 may be configured to drive the rotor 153 to rotate to provide power for the flight of the UAV 110. The power may cause the UAV to realize a movement of one or more degrees of freedom. In some embodiments, the UAV 110 may rotate around one or more rotation axes. For example, the rotation axis may include a roll-axis, a yaw-axis, and a pitch-axis. The motor 152 may include a direct-current (DC) motor or an alternating-current (AC) motor. In addition, the motor 152 may include a brushless motor or a brushed motor.

The flight control system 160 includes a flight controller 161 and a sensor system 162. The sensor system 162 may be configured to measure attitude information of the UAV, that is, position information and status information of the UAV 110 in space, for example, 3D position, 3D angle, 3D speed, 3D acceleration, and 3D angular speed, etc. The sensor system 162, for example, may include at least one of a gyroscope, an ultrasonic sensor, an electronic compass, an inertial measurement unit (IMU), a vision sensor, a global navigation satellite system, or a barometer. For example, the global navigation satellite system may include a global positioning system (GPS). The flight controller 161 may be configured to control the flight of the UAV 110, for example, control the flight of the UAV 110 according to the attitude information measured by the sensor system 162. The flight controller 161 may control the UAV 110 according to program instructions programmed in advance. The flight controller 161 may also control the UAV 110 by responding to one or more control instructions from the control terminal 140.

The gimbal 120 includes a motor 122. The gimbal may be configured to carry a camera device 123. The flight controller 161 may control the movement of the gimbal 120 through the motor 122. In some embodiments, the gimbal 120 further includes a controller, which may be configured to control the motor 122 to control the movement of the gimbal 120. The gimbal 120 may be independent of the UAV 110 or a part of the UAV 110. The motor 122 may include a DC motor or an AC motor. In addition, the motor 122 may include a brushless motor or a brushed motor. The gimbal may be arranged at a top of the UAV or at a bottom of the UAV.

The camera device 123, for example, may include a device configured to capture an image, such as a camera or recorder. The camera device 123 may communicate with the flight controller and photograph under the control of the flight controller. In some embodiments, the camera device 123 may include at least a photosensitive element. The photosensitive element, for example, may include a complementary metal oxide semiconductor (CMOS) sensor or a charge-coupled device (CCD) sensor. The camera device 123 may be directly fixed to the UAV 110, such that the gimbal 120 may be omitted.

The display apparatus 130 may be located at a ground end of the unmanned aerial system 100. The display apparatus 130 may communicate with the UAV 110 wirelessly and may be configured to display the attitude information of the UAV 110. In addition, the image photographed by the camera device 123 may be displayed at the display apparatus 130. The display apparatus 130 may be an independent apparatus or integrated into the control terminal 140.

The control terminal 140 may be located at the ground end of the unmanned aerial system 100. The control terminal 140 may communicate with the UAV 110 wirelessly. The control terminal 140 may be configured to operate the UAV 110 remotely.

In addition, the UAV 110 may carry a loudspeaker (not shown). The loudspeaker may be configured to play an audio file. The loudspeaker may be directly fixed at the UAV 110 or carried by the gimbal 120.

The names of the components of the unmanned aerial system are only for identification purposes, and should not be understood as a limitation to embodiments of the present disclosure.

Magnetic interference may include hard magnetic interference and soft magnetic interference. The hard magnetic interference may refer to an interference of a permanent magnet or a constant magnetic field interference brought by a magnetized ferromagnetic material. The soft magnetic interference may refer to a distortion of a magnetic field distribution caused by a material with high magnetic permeability. The soft magnetic interference may be anisotropic. In the calibration of the magnetic sensor for these two types of interferences, first, two interference sources are required not to move relative to the magnetic sensor, that is, the magnetic sensor and the interference sources are rigidly connected to the body of the mobile platform. Then, a co-shaped calibration method in space may be used to calibrate the magnetic sensor to compensate for an error caused by the magnetic field interference.

The mobile platform may include some mobile magnetic members. These magnetic members may not be rigidly connected to the compass. The magnetic field interference caused by the mobile magnetic members to the magnetic sensor may be compensated by methods of following embodiments to calibrate the magnetic sensor.

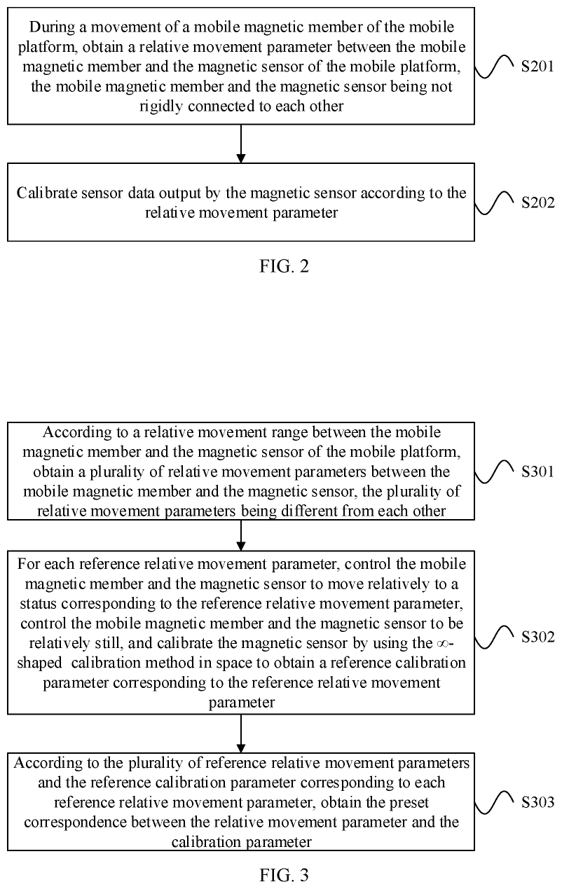

FIG. 2 is a schematic flowchart of a magnetic sensor calibration method according to some embodiments of the present disclosure. As shown in FIG. 2, in some embodiments, the method includes the following processes.

At S201, during a movement of a mobile magnetic member of the mobile platform, a relative movement parameter between the mobile magnetic member and the magnetic sensor of the mobile platform is obtained. The mobile magnetic member and the magnetic sensor are not rigidly connected to each other.

In some embodiments, the mobile magnetic member may include any component, which can interfere the operation of the magnetic sensor, of the mobile platform. The mobile magnetic member may move relative to the magnetic sensor. The mobile magnetic member may include a ferromagnetic member or a component with high magnetic permeability. For example, the mobile magnetic member may include the gimbal, the motor, a moving rail, a mobile swing arm, a crank rocker, etc., which is not limited by embodiments of the present disclosure.

The magnetic sensor may include any sensor that functions by sensing the magnetic field or by a magnetic force, for example, a compass, a magnetometer, or a position sensor, etc.

In some embodiments, the mobile magnetic member and the magnetic sensor of the mobile platform are not connected rigidly. When the mobile magnetic member moves, a movement relative to the magnetic sensor may be generated to interfere with the operation of the magnetic sensor. Therefore, in some embodiments, when the mobile magnetic member moves, the relative movement parameter between the mobile magnetic member and the magnetic sensor may be obtained.

Obtaining the relative movement parameter between the mobile magnetic member and the magnetic sensor may include obtaining relative movement parameters between the mobile magnetic member and the magnetic sensor at multiple moments. That is, the relative movement parameter between the mobile magnetic member and the magnetic sensor may be obtained at each moment of the multiple moments during movement of the mobile magnetic member.

In some embodiments, the relative movement parameter may include at least one of a relative position or a relative attitude. In some embodiments, during the movement of the mobile magnetic member of the mobile platform, if the relative position of the mobile magnetic member and the magnetic sensor changes during movement of the mobile platform, the relative position between the mobile magnetic member and the magnetic sensor of the mobile platform may be obtained. In some other embodiments, if the relative attitude between the mobile magnetic member and the magnetic sensor changes during the movement of the mobile magnetic member of the mobile platform, the relative attitude between the mobile magnetic member and the magnetic sensor of the mobile platform may be obtained. In some embodiments, if the relative position and the relative attitude between the mobile magnetic member and the magnetic sensor change during the movement of the mobile magnetic member, the relative position and the relative attitude between the mobile magnetic member and the magnetic sensor of the mobile platform may be obtained.

The relative movement parameter may not be limited to this. For example, the relative movement parameter may further include a relative speed and/or a relative acceleration. In some embodiments, the relative position may include a relative distance. In some other embodiments, the relative position may include the relative distance and relative location.

In some embodiments, if the magnetic sensor is rigidly connected to the vehicle body of the mobile platform, the movement of the mobile magnetic member may be considered as the relative movement between the mobile magnetic member and the magnetic sensor.

In some embodiments, obtaining the relative position of the mobile magnetic member relative to the magnetic sensor may include obtaining the relative position between the mobile magnetic member and the magnetic sensor through a position sensor carried at the mobile magnetic member.

In some embodiments, the relative movement between the mobile magnetic member and the magnetic sensor may cause the relative position between the mobile magnetic member and the magnetic sensor to change. For example, for some UAVs that can change the configuration of the stand during flight, the motor that drives the rotor of the UAV may be arranged at the stand, and the magnetic sensor may be rigidly connected to the vehicle body of the UAV. When the configuration of the stand of the UAV changes, the motor may move relative to the magnetic sensor, and the relative position between the motor and the magnetic sensor may change. For such a situation, the position sensor may be arranged at the mobile magnetic member. The position sensor may include a sensor that can measure a position change, for example, a distance sensor, an angle sensor, etc. The mobile platform may obtain measured data output by the position sensor and obtain the relative position between the mobile magnetic member and the magnetic sensor according to the measured data.

In some embodiments, obtaining the relative attitude of the mobile magnetic member relative to the magnetic sensor may include obtaining the relative attitude between the mobile magnetic member and the magnetic sensor through the attitude sensor carried by the mobile magnetic member.

In some embodiments, the relative movement between the mobile magnetic member and the magnetic sensor may cause the relative attitude between the mobile magnetic member and the magnetic sensor to change. For example, the gimbal may be arranged at the mobile platform. The gimbal may be connected to the body of the mobile platform. The magnetic sensor may be rigidly connected to the vehicle body of the UAV. When the attitude of the gimbal changes, the gimbal may move relative to the magnetic sensor. The relative attitude between the gimbal and the magnetic sensor may change. For such a situation, the attitude sensor may be carried at the mobile magnetic member. The attitude sensor may include a sensor that can measure the attitude change, for example, an IMU. The mobile platform may obtain measured data output by the attitude sensor and obtain the relative attitude between the mobile magnetic member and the magnetic sensor according to the measured data.

At S202, sensor data output by the magnetic sensor is calibrated according to the relative movement parameter.

In some embodiments, due to the relative movement between the mobile magnetic member and the magnetic sensor, the relative movement parameters between the mobile magnetic member and the magnetic sensor may be different at different moments, and the mobile magnetic member may impact the magnetic sensor differently. During the calibration of the sensor data output by the magnetic sensor, the relative movement parameters between the mobile magnetic member and the magnetic sensor may need to be obtained at multiple moments. After the relative movement parameter between the mobile magnetic member and the magnetic sensor is obtained, the sensor data output by the magnetic sensor may be calibrated according to the relative movement parameter. Further, the sensor data output by the magnetic sensor may be calibrated according to the relative movement parameters between the mobile magnetic member and the magnetic sensor at multiple moments. As such, during the movement of the mobile magnetic member, the sensor data output by the magnetic sensor may be calibrated in real-time for the different relative movement parameters.

The sensor data output by the magnetic sensor may include the measured data output by the magnetic sensor, for example, magnetic field strength or heading.

In some embodiments, the relative movement parameter between the mobile magnetic member and the magnetic sensor may be obtained during the movement of the mobile magnetic member. The sensor data output by the magnetic sensor may be calibrated according to the relative movement parameter. As such, in a scene when the magnetic sensor moves relative to the mobile magnetic member, the magnetic sensor may be effectively calibrated, and the accuracy of the parameter measurement may be improved.

In some embodiments, implementing process S202 includes determining a calibration parameter of the magnetic sensor according to the relative movement parameter and calibrating the sensor data output by the magnetic sensor according to the calibration parameter of the magnetic sensor.

In some embodiments, the calibration parameter used to calibrate the magnetic sensor may be determined according to the relative movement parameter between the mobile magnetic member and the magnetic sensor first. The calibration parameter may include a parameter that can be used to calibrate the sensor data output by the magnetic sensor. Further, the calibration parameter of each moment of the multiple moments may be determined according to the relative movement parameters between the mobile magnetic member and the magnetic sensor at the multiple moments. The calibration parameter may include at least one of a displacement, an offset, or a measurement range. After the calibration parameter is determined, the sensor data output by the magnetic sensor may be calibrated according to the calibration parameter. Further, the sensor data output by the magnetic sensor at the multiple moments may be calibrated according to the calibration parameters at the multiple moments. Since the sensor data output by the magnetic sensor is calibrated, accurately measured data may be obtained.

The sensor data may include at least one of sensor data in a pitch direction, sensor data in a yaw direction, or sensor data in a roll direction.

For example, the sensor data may include at least one of magnetic field strength in the pitch direction, magnetic field strength in the yaw direction, or magnetic field strength in the roll direction.

As another example, the sensor data may include at least one of a heading in the pitch direction, a heading in the yaw direction, or a heading in the roll direction.

Correspondingly, the calibration parameter may include at least one of a calibration parameter in the pitch direction, a calibration parameter in the yaw direction, or a calibration parameter in the roll direction.

In some embodiments, according to the relative movement parameter, determining the calibration parameter of the magnetic sensor includes according to the relative movement parameter and a preset correspondence between the relative movement parameter and the calibration parameter, obtaining the calibration parameter of the magnetic sensor.

In some embodiments, the correspondence between the relative movement parameter and the calibration parameter may be preset. After the relative movement parameter between the mobile magnetic member and the magnetic sensor is obtained, according to the correspondence, the calibration parameter corresponding to the relative movement parameter may be obtained, and the calibration parameter may be determined to be the calibration parameter of the magnetic sensor. The correspondence may be stored in a storage device of the mobile platform.

For example, the correspondence may include a mapping table between the relative movement parameter and the calibration parameter. The calibration parameter corresponding to the relative movement parameter may be obtained by querying the mapping table.

As shown in FIG. 3, obtaining the correspondence includes following processes S301-S303.

At S301, according to a relative movement range between the mobile magnetic member and the magnetic sensor of the mobile platform, a plurality of relative movement parameters between the mobile magnetic member and the magnetic sensor are obtained. The plurality of relative movement parameters can be different from each other.

In some embodiments, the relative movement range between the mobile magnetic member and the magnetic sensor of the mobile platform may be discretized appropriately, that is, the whole relative movement range may be divided into a limited number of continuous movement sections at an equal interval. A starting reference relative movement parameter of each section may be used as a quantized parameter of the section, that is, a reference relative movement parameter. During discretization, on an aspect, by considering resource occupation, such as the more sections the whole relative movement range is divided into, the larger the storage space the calibration parameters occupy. The fewer sections the whole relative movement range is divided into, the worse the calibration effect is. A specific implementation may be determined according to specific situations.

At S302, for each reference relative movement parameter, the mobile magnetic member and the magnetic sensor are controlled to move relatively to a status corresponding to the reference relative movement parameter, the mobile magnetic member and the magnetic sensor are controlled to be relatively still. The magnetic sensor may be calibrated by using the ∞-shaped calibration method in space to obtain a reference calibration parameter corresponding to the reference relative movement parameter.

In some embodiments, after the plurality of reference relative movement parameters are obtained, for each reference relative movement parameter, the mobile magnetic member and the magnetic sensor of the mobile platform may be controlled to move relative to the status corresponding to the reference relative movement parameter. Then, the mobile magnetic member and the magnetic sensor may stop to be controlled to move, that is, the mobile magnetic member and the magnetic sensor may be maintained to be relatively still. Then, under the status that the mobile magnetic member and the magnetic sensor are relatively still, the magnetic sensor may be calibrated by using the ∞-shaped calibration method in space to obtain the calibration parameter used to compensate for the magnetic field interference caused by the relative movement. The calibration parameter may be determined as the reference calibration parameter corresponding to the reference relative movement parameter. For each reference relative movement parameter, a same operation may be performed to obtain the reference calibration parameter corresponding to each reference relative movement parameter of the plurality of reference relative movement parameters.

At S303, according to the plurality of reference relative movement parameters and the reference calibration parameter corresponding to each reference relative movement parameter, the preset correspondence between the relative movement parameter and the calibration parameter is obtained.

In some embodiments, the correspondence, for example, may include the mapping table of each reference relative movement parameter and the reference calibration parameter.

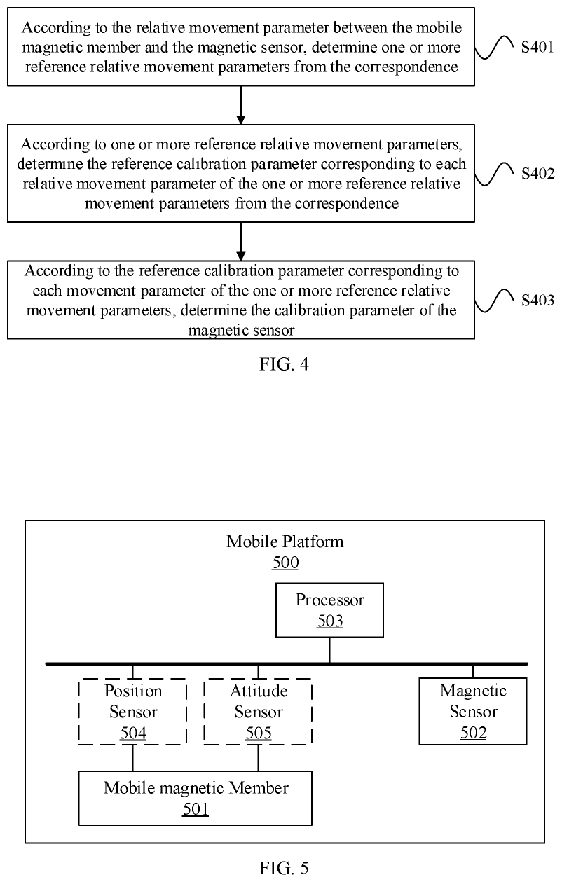

In some embodiments, as shown in FIG. 4, according to the relative movement parameter and the preset correspondence between the relative movement parameter and the calibration parameter, obtaining the calibration parameter of the magnetic sensor includes following processes S401-S403.

At S401, according to the relative movement parameter between the mobile magnetic member and the magnetic sensor, one or more reference relative movement parameters are determined from the correspondence.

In some embodiments, one or more reference relative movement parameters of the relative movement between the mobile magnetic member and the magnetic sensor may be determined by querying the correspondence. The reference relative movement parameters may include relative movement parameters around the relative movement parameters (e.g., neighboring relative movement parameters). For example, if the relative movement parameter falls into one of the movement sections, the starting reference relative movement parameter of the movement section may be used as the reference relative movement parameter of the relative movement parameter. In some other embodiments, the starting reference relative movement parameter and an ending reference relative movement of the movement section may be used as two reference relative movement parameters of the relative movement. The ending reference relative movement parameter may be a starting reference relative movement parameter of a next movement section of the movement section.

At S402, according to one or more reference relative movement parameters, the reference calibration parameter corresponding to each relative movement parameter of the one or more reference relative movement parameters is determined from the correspondence.

After the one or more reference relative movement parameters are determined, the calibration parameter corresponding to each reference relative movement parameter may be determined according to the correspondence, that is, the reference calibration parameter.

At S403, according to the reference calibration parameter corresponding to each movement parameter of the one or more reference relative movement parameters, the calibration parameter of the magnetic sensor is determined.

When one reference relative movement parameter is included, the calibration parameter corresponding to the reference relative movement parameter may be determined to be the calibration parameter of the magnetic sensor. In some embodiments, a product of the reference calibration parameter corresponding to the reference relative movement parameter and a preset coefficient may be determined as the calibration parameter of the magnetic sensor, which is not limited in embodiments of the present disclosure.

In some embodiments, when a plurality of reference relative movement parameters are included, interpolation may be performed on the reference calibration parameter corresponding to each movement parameter of the plurality of reference relative movement parameters to obtain the calibration parameter of the magnetic sensor.

For example, two reference relative movement parameters may be included, a first reference relative movement parameter and a second reference relative movement parameter. The first reference relative movement parameter corresponds to a first reference calibration parameter. The second reference relative movement parameter corresponds to a second reference calibration parameter.

In some embodiments, when the interpolation is performed on the reference calibration parameters, there is no need to refer to the reference relative movement parameters corresponding to the reference calibration parameters. The calibration parameter of the magnetic sensor, for example, may be (the first reference calibration parameter+the second reference calibration parameter)/2 or (the first reference calibration parameter×a first coefficient)+(the second reference calibration parameter×a second coefficient), which is not limited in embodiments of the present disclosure.

In some embodiments, when the interpolation is performed on the reference calibration parameters, reference may be made to the reference relative movement parameters corresponding to the reference calibration parameters. The calibration parameter of the magnetic sensor, for example, may include the calibration parameter corresponding to the relative movement parameter obtained by performing the interpolation according to the relative movement parameters between the mobile platform and the magnetic sensor, the first reference relative movement parameter, the first reference calibration parameter, the second reference relative movement parameter, and the second reference calibration parameter.

Embodiments of the present disclosure further provide a computer storage medium. The computer storage medium stores program instructions. When program instructions are executed, a part of or all processes of the magnetic sensor calibration method of embodiments of the present disclosure may be included.

FIG. 5 is a schematic structural diagram of a mobile platform 500 according to some embodiments of the present disclosure. As shown in FIG. 5, the mobile platform 500 of embodiments of the present disclosure includes a mobile magnetic member 501, a magnetic sensor 502, and a processor 503. The mobile magnetic member 501 and the magnetic sensor 502 are not rigidly connected. The processor 503 is connected to the mobile magnetic member 501 and the magnetic sensor 502.

The processor 503 may be configured to obtain a relative movement parameter between the mobile magnetic member 501 and the magnetic sensor 502 during movement of the mobile magnetic member 501 and calibrate sensor data output by the magnetic sensor 502 according to the relative movement parameter.

In some embodiments, the processor 503 may be configured to determine a calibration parameter of the magnetic sensor 502 according to the relative movement parameter and calibrate the sensor data output by the magnetic sensor 502 according to the calibration parameter of the magnetic sensor 502.

In some embodiments, the calibration parameter may include at least one of a displacement, an offset, or a measurement range.

In some embodiments, the processor 503 may be configured according to the relative movement parameter and a preset correspondence between the relative movement parameter and the calibration parameter, obtain the calibration parameter of the magnetic sensor 502.

In some embodiments, the processor 503 may be configured to determine one or more reference relative movement parameters from the correspondence according to the relative movement parameters, determine a calibration parameter corresponding to each reference movement parameter of the one or more reference relative movement parameters according to the one or more reference relative movement parameters, and determine the calibration parameter of the magnetic sensor 502 according to the reference calibration parameter corresponding to each reference movement parameter of the one or more reference relative movement parameters.

In some embodiments, the processor 503 may be configured to perform interpolation on the reference calibration parameter corresponding to each reference movement parameter of a plurality of reference relative movement parameters to obtain the calibration parameter of the magnetic sensor 502.

In some embodiments, the sensor data may include at least one of sensor data in a pitch direction, sensor data in a yaw direction, or sensor data in a roll direction.

In some embodiments, the relative movement parameter may include at least one of a relative position and a relative attitude.

In some embodiments, the magnetic sensor 502 may be rigidly connected to a body of the mobile platform 500. The mobile platform 500 further includes a position sensor 504 and/or an attitude sensor 505. The position sensor 504 may be arranged at the mobile magnetic member 501. The attitude sensor 505 may be arranged at the mobile magnetic member 501.

The processor 503 may be configured to obtain the relative position between the mobile magnetic member 501 and the magnetic sensor 502 using the position sensor 504 and/or the relative attitude between the mobile magnetic member 501 and the magnetic sensor 502 using the attitude sensor 505.

In some embodiments, the mobile magnetic member 501 may include a gimbal, a motor, a moving rail, a mobile swing arm, and a crank rocker.

In some embodiments, the mobile platform 500 of embodiments of the present disclosure further includes a storage device (not shown). The storage device stores program instructions that, when executed, cause the mobile platform 500 to implement the technical solutions of embodiments of the present disclosure.

The mobile platform 500 of embodiments of the present disclosure may be configured to implement the technical solutions of method embodiments of the present disclosure, which has a similar principle and technical effects and is not repeated here.

Those of ordinary skill in the art can understand that all or part of the processes in method embodiments may be implemented by a program instructing relevant hardware. The program may be stored in a computer-readable storage medium. When the program is executed, processes of method embodiment are performed. The storage medium may include various media, such as a read-only memory (ROM), a random access memory (RAM), magnetic disks, or optical disks, etc., that can store program codes.

embodiments of the present disclosure are only used to illustrate the technical solutions of the present disclosure, but not to limit them. Although the present disclosure has been described in detail with reference to embodiments of the present disclosure, those of ordinary skill in the art should understand that modifications may be performed on the technical solutions of embodiments of the present disclosure, or equivalent replacement may be performed on some or all of the technical features. These modifications or replacements do not cause the essence of the corresponding technical solutions to depart from the scope of the technical solutions of embodiments of the present disclosure.

What is claimed is:

1. A magnetic sensor calibration method comprising:
obtaining a relative movement parameter between a mobile magnetic member of a mobile platform and a magnetic sensor of the mobile platform during movement of the mobile magnetic member, the mobile magnetic member and the magnetic sensor being not rigidly connected to each other; and
calibrating sensor data output by the magnetic sensor according to the relative movement parameter.

2. The method of claim 1, wherein calibrating the sensor data output by the magnetic sensor according to the relative movement parameter includes:
determining a calibration parameter of the magnetic sensor according to the relative movement parameter; and
calibrating the sensor data output by the magnetic sensor according to the calibration parameter of the magnetic sensor.

3. The method of claim 2, wherein the calibration parameter includes at least one of a displacement, an offset, or a measurement range.

4. The method of claim 2, wherein determining the calibration parameter of the magnetic sensor according to the relative movement parameter includes:
obtaining the calibration parameter of the magnetic sensor according to the relative movement parameter and a preset correspondence between the relative movement parameter and the calibration parameter.

5. The method of claim 4, wherein obtaining the calibration parameter of the magnetic sensor according to the relative movement parameter and the preset correspondence between the relative movement parameter and the calibration parameter includes:
determining one or more reference relative movement parameters from the correspondence according to the relative movement parameter;
determining one or more reference calibration parameters from the correspondence according to the one or more reference relative movement parameters, each of the one or more reference calibration parameters corresponding to one of the one or more reference relative movement parameters; and
determining the calibration parameter of the magnetic sensor according to the one or more reference calibration parameters.

6. The method of claim 5, wherein:
the one or more reference relative movement parameters include a plurality of reference relative movement parameters, and the one or more reference calibration parameters includes a plurality of reference calibration parameters each corresponding to one of the plurality of reference relative movement parameters; and
determining the calibration parameter of the magnetic sensor according to the one or more reference calibration parameters includes performing interpolation on the plurality of reference calibration parameters to obtain the calibration parameter of the magnetic sensor.

7. The method of claim 1, wherein the sensor data includes at least one of sensor data in a pitch direction, sensor data in a yaw direction, or sensor data in a roll direction.

8. The method of claim 1, wherein the relative movement parameter includes at least one of a relative position or a relative attitude.

9. The method of claim 8, wherein:
the magnetic sensor is rigidly connected to a body of the mobile platform; and
obtaining the relative movement parameter includes at least one of:
obtaining the relative position between the mobile magnetic member and the magnetic sensor by a position sensor carried at the mobile magnetic member; or
obtaining the relative attitude between the mobile magnetic member and the magnetic sensor by an attitude sensor carried at the mobile magnetic member.

10. The method of claim 1, wherein the mobile magnetic member includes at least one of a gimbal, a motor, a moving rail, a mobile swing arm, or a crank rocker.

11. A mobile platform comprising:
a mobile magnetic member;
a magnetic sensor not rigidly connected to the mobile magnetic member; and
a processor configured to:
obtain a relative movement parameter between the mobile magnetic member and the magnetic sensor during movement of the mobile magnetic member; and
calibrate sensor data output by the magnetic sensor according to the relative movement parameter.

12. The mobile platform of claim 11, wherein the processor is further configured to:
determine a calibration parameter of the magnetic sensor according to the relative movement parameter; and
calibrate the sensor data output by the magnetic sensor according to the calibration parameter of the magnetic sensor.

13. The mobile platform of claim 12, wherein the calibration parameter includes at least one of a displacement, an offset, or a measurement range.

14. The mobile platform of claim 12, wherein the processor is further configured to:
obtain the calibration parameter of the magnetic sensor according to the relative movement parameter and a preset correspondence between the relative movement parameter and the calibration parameter.

15. The mobile platform of claim 14, wherein the processor is further configured to:
determine one or more reference relative movement parameters from the correspondence according to the relative movement parameter;
determine one or more reference calibration parameters from the correspondence according to the one or more reference relative movement parameters, each of the one or more reference calibration parameters corresponding to one of the one or more reference relative movement parameters; and
determine the calibration parameter of the magnetic sensor according to the one or more reference calibration parameters.

16. The mobile platform of claim 15, wherein:
the one or more reference relative movement parameters include a plurality of reference relative movement parameters, and the one or more reference calibration parameters includes a plurality of reference calibration parameters each corresponding to one of the plurality of reference relative movement parameters; and
the processor is further configured to perform interpolation on the plurality of reference calibration parameters to obtain the calibration parameter of the magnetic sensor.

17. The mobile platform of claim 11, wherein the sensor data includes at least one of sensor data in a pitch direction, sensor data in a yaw direction, or sensor data in a roll direction.

18. The mobile platform of claim 11, wherein the relative movement parameter includes at least one of a relative position or a relative attitude.

19. The mobile platform of claim 18, further comprising:
a position sensor carried at the mobile magnetic member; and
an attitude sensor carried at the mobile magnetic member;
wherein:
the magnetic sensor is rigidly connected to a body of the mobile platform; and
the processor is further configured to:
obtain the relative position between the mobile magnetic member and the magnetic sensor by the position sensor; or
obtain the relative attitude between the mobile magnetic member and the magnetic sensor by the attitude sensor.

20. The mobile platform of claim 11, wherein the mobile magnetic member includes at least one of a gimbal, a motor, a moving rail, a mobile swing arm, or a crank rocker.
